(19) United States
(12) Patent Application Publication
(10) Pub. No.: US 2012/0098111 A1
(43) Pub. Date: Apr. 26, 2012

(54) High current capacity inner leads for semiconductor devices, interposer and leadframe

(76) Inventor: Solomon David Edlin, Rishon Lezion (IL)

(21) Appl. No.: 13/136,107

(22) Filed: Jul. 25, 2011

(30) Foreign Application Priority Data
Aug. 9, 2010 (IL) 208912

(51) Int. Cl. H01L 23/495; H01L 23/34; H05K 1/09

(52) U.S. Cl. 257/675; 257/676; 174/257; 257/E23.031; 257/E23.08

(57) ABSTRACT

The invention can be used for improving performance of laser diodes, solar cells, microprocessors and other devices. The invention enables to create semiconductor devices and systems comprising several electronic components and having a great area of die, a great number of leads, high operating current and high heat dissipation. This is achieved by the following manner: offered leads are made of copper foil; the rigidity of the foil is decreased by means of creating of alternating narrow trenches and narrow through splits; the offered leads are microspring; additional improvement of performance can be achieved by the bending of inner leads along wide trenches. Offered leads can be directly connected to the dice.

The invention relates to microelectronics and more particularly to the structure of inner leads of semiconductor devices, integral circuits and systems.

### BACKGROUND OF THE INVENTION

The invention enables to create semiconductor devices and systems comprising several electronic components (board, display, chip) and having dice with great area, a great number of leads, high operating current and high heat dissipation.

There exists a method for attaching leads to die [1]. Electrical connection is made by a strip of anisotropically conductive elastomeric material, preferably a multilayer laminate consisting of alternating parallel sheets of a conductive foil and an insulating elastomer wherein the laminate layers are oriented perpendicular to both the bond pad and the lead.

There exists a method for fabricating an ultrahigh density compliant chip input/output interconnections [2]. A polymer film with embedded air gaps provides substantially higher compliance than polymer film without embedded air gaps. A chip with 12000 cm.sup.-2 compliant I/O leads are demonstrated.

There exists a method for soldering Si chip to Cu substrate comprising thick layers of solder [3]. The disadvantages are low thermal conductivity and low electrical conductivity because of high thickness of solder (about 10.sup.-4m).

There exists a bumpless method of attaching inner leads to semiconductor integrated circuits [4]. A lead frame of copper foil is disposed parallel to chip surface. The disadvantage is necessary to heat the inner leads to high temperature.

There exists a method and apparatus for plasma etching of Cu-containing layers in semiconductor devices using an aluminum source in the presence of a halogen-containing plasma [5]. The aluminum source reacts with halogenated Cu-containing surfaces and forms volatile etch products that allows for anisotropic etching Cu-containing layers using conventional plasma etching tools.

There exists a comprehensive modeling methodology for the investigation of on-chip noise generation and coupling due to power switching [6]. The distributed resistance, inductance, capacitance and conductance circuits for signal wires are extracted and used to provide for a transmission line-based modelling of crosstalk and power grid induced signal degradation. The transmission line is connected to die with many wires. The lead pin pitch equals 3.times.10.sup.-5 m.

There exists an application for power transistor [7]. The transistor has six leads. The transistor provides high current density.

There exists an application for high current capacity inner leads for semiconductor devices [8]. The inner leads can serve as power supply buses for different devices.

### BRIEF SUMMARY OF INVENTION

The external forces and the coefficient of thermal expansion mismatch between silicon die, materials of package and leads determine the choice of the structure of latter. Offered leads are made of copper foil coated with gold or silver; rigidity of the foil is decreased by means of creating of alternating narrow trenches on both side foil and/or narrow and wide through splits. The lead becomes a microspring. The narrow trenches and splits can be either perpendicular to contact pads of a semiconductor die or non-perpendicular as well as non-straightforward. A compliance of the lead (FIG. 3, FIG. 21) along trenches and splits is low, but the compliance of the lead perpendicular to trenches and splits is high. End of compliant lead can be lightly turn relatively any axis. A decrease of the distance between the next of the trenches and splits and an increase of the length of the trenches and splits lead to an increase of the compliance of the leads. Hence, it is possible to select necessary rigidity.

An additional decrease of rigidity can be achieved by means of bending of the foil along wide trenches, which are created for this aim (flexible leads; microsprings). The leads become compliant and flexible ones. The compliant leads protect the die from high stress. Can create multilayer lead. The layers can be different. Upper layer can be, for example, continuous i.e. without any trenches and splits. The lead is heatspreader.

The offered lead can serves as a power supply bus, signal lead, an interconnection structure, external lead. The offered leads can be connected to external leads that are the part of a package. The area of the section of offered leads is commensurable with an area of the die. Offered leads enable to pass a high current density. Besides, offered flexible leads enable to use die having a great area. Hence, offered leads enable to manufacture semiconductor devices having a high operating current. A decrease of conductivity of the leads because of the trenches and splits is inessential.

The offered leads can be disposed either parallel to die or perpendicular to it. It is possible to produce a device comprising, for example, 5000 cm.sup.-2 signal leads (50 rows with 100 leads in each row). The leads can be produced with help of a lead-frame. The alone lead or lead stack can be connected to horizontal leadframe to increase current capacity. Heat and electrical current can flow through offered leads to water-cooled buses.

The inner leads of integral circuit can be either parallel to each other or non-parallel of ones. The inner leads can be joined with a lead connecting strip, a lead-fixing tape or other manners.

The leads can be pack by adhesive bonding. It is necessary to take into consideration a loss of energy in the adhesive bonding at high frequency.

Coating with noble metal, the first dry anisotropic etching of narrow and wide trenches (depth of etching equals 50 percent thickness of foil), glueing of a lead fixing tape, the second dry anisotropic etching of narrow and wide trenches (forming narrow through splits), bending, and connecting the inner leads to contact pads and external leads are manufactured by known technique, for example, soldering with soft solder.

The barrier film has used to protect the semiconductor die from Cu, Au or Ag doping.

This result is achieved by making at least one of leads of a semiconductor device of copper foil comprising alternating narrow trenches on both side said foil and/or a row of narrow through splits; the next of said splits are disposed at a distance several times less than the thickness of said foil; long narrow facet of said lead is directly connected to at least one of the contact pads of an electronic component (die); said splits are disposed near said contact pad.

This result is achieved by disposing the next of said trenches at a distance equal approximately the thickness of said foil.

This result is achieved by creating a depth of said trench equal to about 50 percent of said thickness of said foil.

This result is achieved by creating said splits and said trenches parallel to each other.

This result is achieved by creating a height of said lead many times greater than said thickness of said foil.

This result is achieved by creating a length of said split equal to about 20 percent of said height of said lead.

This result is achieved by creating said splits and said trenches non-straightforward.

This result is achieved by coating said lead with gold or silver.

This result is achieved by connecting said lead to said contact pad with solder; the thickness of said solder is equal to about 3.times.10.sup.-6 m.

This result is achieved by the fact that said lead is the part of a heatspreader.

This result is achieved by further comprising a lead fixing tape.

This result is achieved by making at least one of leads of a semiconductor device of copper foil comprising alternating narrow trenches on both side said foil and/or two rows of narrow through splits; the next of said splits are disposed at a distance several times less than the thickness of said foil; long narrow facet of said lead is directly connected to the contact pads of two electronic components; said splits are disposed near said contact pads.

This result is achieved by disposing the next of said trenches at a distance equal approximately the thickness of said foil.

This result is achieved by creating a depth of said trench equal to about 50 percent of said thickness of said foil.

This result is achieved by creating said splits and said trenches parallel to each other.

This result is achieved by creating a height of said lead many times greater than said thickness of said foil.

This result is achieved by creating a length of said split equal to about 20 percent of said height of said lead.

This result is achieved by creating said splits and said trenches non-straightforward.

This result is achieved by coating said lead with gold or silver.

This result is achieved by connecting said lead to said contact pad with solder; the thickness of said solder is equal to about 3.times.10.sup.-6 m.

This result is achieved by the fact that said lead is the part of a heatspreader.

This result is achieved by further comprising a lead fixing tape.

This result is achieved by creating the lead stack comprising a great number of leads of a semiconductor device separated each other by the isolation; said leads are made of copper foil comprising alternating narrow trenches on both side said foil and/or one or two rows narrow through splits; long narrow facets of said leads are directly connected to the contact pads one or two electron components; said splits are disposed near said contact pads.

This result is achieved by disposing the next of said trenches at a distance equal approximately the thickness of said foil.

This result is achieved by creating a depth of said trench equal to about 50 percent of said thickness of said foil.

This result is achieved by connecting said lead stack to said contact pads that are a number of parallel strips; said leads are connected to external leads that are the part of a package.

This result is achieved by further comprising parallel wide trenches disposed at upper part of inner leads; said leads are bent along said wide trenches.

This result is achieved by making great leads and a great number of signal leads of copper foil; great leads comprise alternating narrow trenches on both side said foil and/or two rows of narrow through splits; the next of said great lead splits are disposed at a distance several times less than the thickness of said foil; long narrow facets of said great leads are directly connected to the contact pads of two electronic components; said great lead splits are disposed near said contact pads; said signal lead comprises alternating narrow trenches on both side said foil and/or alternating narrow through splits on both sides of said signal lead; the row of said signal leads is disposed between two lead fixing tapes and two said great leads; said signal leads are directly connected to the contact pads of two said electronic components.

This result is achieved by disposing the next of said trenches at a distance equal approximately the thickness of said foil.

This result is achieved by creating a depth of said trench equal to about 50 percent of said thickness of said foil.

This result is achieved by the fact that said signal lead has height equal to height said great lead.

This result is achieved by creating said splits and said trenches parallel to each other.

This result is achieved by creating signal lead width equal to about 2.times.thickness of said foil; said signal lead splits have a length equal to about 60 percent of said width of said lead; the next of said signal lead splits are disposed at a distance equal to about the width of said signal lead.

This result is achieved by coating said lead with gold or silver.

This result is achieved by connecting said lead to said contact pad with solder; the thickness of said solder is equal to about 3.times.10.sup.-6 m.

This result is achieved by creating the leadframe comprising a great number of inner leads and at least one external leads; said leadframe is made of copper foil; said inner leads comprise alternating narrow trenches on both side said foil and/or alternating narrow through splits on both sides of said leads; said inner leads can comprise wide trenches; said inner leads are bent along said wide trenches; said inner leads are directly connected to contact pads disposed on one or both major surfaces of at least one electronic component; said inner leads can be formed into a two-layer and/or multilayer structure.

This result is achieved by disposing the next of said trenches at a distance equal approximately the thickness of said foil.

This result is achieved by creating a depth of said trench equal to about 50 percent of said thickness of said foil.

This result is achieved by creating lead width equal about 2.times.thickness of said foil; said splits have a length equal about 60 percent of said width of said lead; the next of said splits are disposed at a distance equal to about the width of said lead.

This result is achieved by coating said leadframe with gold or silver.

This result is achieved by connecting said inner leads to said contact pads with solder; the thickness of said solder is equal to about 3.times.10.sup.-6 m.

This result is achieved by the fact that said leadframe is the part of a heatspreader.

This result is achieved by further comprising a lead connecting strip.

This result is achieved by using shape and dimensions of layers different.

The leads with an offered combination of features are unknown therefore the offered leads correspond to the criterion “novelty”.

The offered combination of features does not obviously follow from the engineering level, technical performance is not known from prior art, therefore the leads correspond to the criterion “invention level”.

The purpose of the invention and the means and methods of its realization are indicated in the application documents, its purpose being realizable, which means there is “industrial applicability”.

### BRIEF DESCRIPTION OF THE DRAWING

FIG. 1 represents the connection of contact pads of die with leads by an anisotropically conductive elastomeric strip (prior art).

FIG. 2 represents the connection of contact pads of die to offered leads.

FIG. 3 represents the disposition of splits of lead. The first of many embodiments.

FIG. 4 represents the disposition of splits of lead. The second of many embodiments.

FIG. 5 represents the disposition of splits of lead. The third of many embodiments.

FIG. 6 represents the disposition of contact pads of power transistor. (Scale has not been kept. One of several embodiments; for illustration only).

FIG. 7 represents the structure of leads of power transistor. (Scale has not been kept. One of several embodiments; for illustration only).

FIG. 8 represents the structure of leads of power transistor. (Scale has not been kept. One of several embodiments; for illustration only).

FIG. 9 represents the disposition contact pads for interposer. (Scale has not been kept. One of many embodiments; for illustration only).

FIG. 10 represents the shape of signal lead with trenches. (Scale has not been kept. One of many embodiments; for illustration only).

FIG. 11 represents the shape of signal lead with splits. (Scale has not been kept. One of many embodiments; for illustration only).

FIG. 12 represents the disposition two leadframes on the die. (Scale has not been kept. One of many embodiments; for illustration only).

FIG. 13 represents the connection of five electronic components with help of offered leadframe. (Scale has not been kept. One of many embodiments; for illustration only).

FIG. 14 represents the connection of five electronic components with help of offered leadframe. (Scale has not been kept. One of many embodiments; for illustration only).

FIG. 15 represents the connection of eight electronic components with help of offered leadframe. (Scale has not been kept. One of many embodiments; for illustration only).

FIG. 16 represents the connection of ten electronic components with help of offered leadframe. (Scale has not been kept. One of many embodiments; for illustration only).

FIG. 17 represents the structure of leads of solar cell with help of offered leadframe. (Scale has not been kept. One of many embodiments; for illustration only).

FIG. 18 represents the power leadframe structure. The first embodiment.

FIG. 19 represents the power leadframe structure. The second embodiment.

FIG. 20 represents the power leadframe structure. The third embodiment.

FIG. 21 represents the disposition of trenches of foil. The first of many embodiments.

FIG. 22 represents the disposition of trenches of foil. The second of many embodiments.

FIG. 23 represents the disposition of trenches of foil. The third of many embodiments.

FIG. 24 represents the structure of leads of relatively power transistor. (Scale has not been kept. One of several embodiments; for illustration only).

### DETAIL DESCRIPTION OF THE PREFERRED EMBODIMENTS

Connection of contact pads with leads FIG. 1 comprises chip 1, contact pad 2, lead 3, conductive foil 4, insulating elastomer 5, anisotropically conductive elastomeric material strip 6.

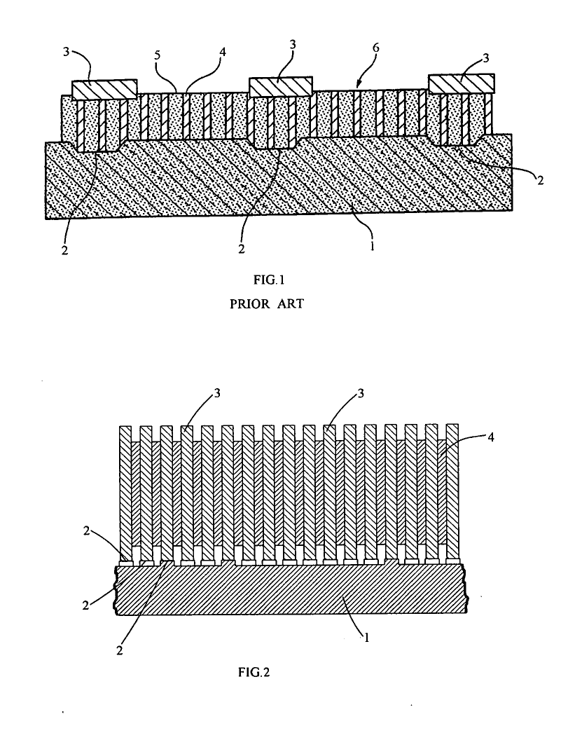

Connection of contact pads with leads FIG. 2 comprises chip 1, contact pad 2, lead 3, lead fixing tape (isolation) 4.

Thickness of the isolating film equals approximately the thickness of the foil.

Isolation can be made, for example, of polytetrafluoreethylene.

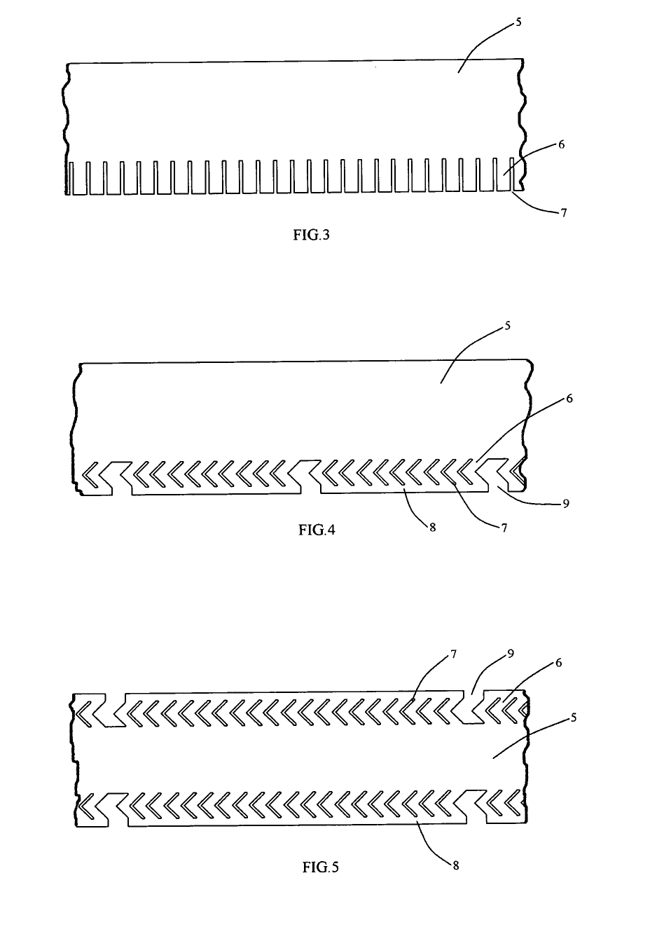

Disposition of splits FIG. 3 comprises lead 5, leg 6, narrow split 7.

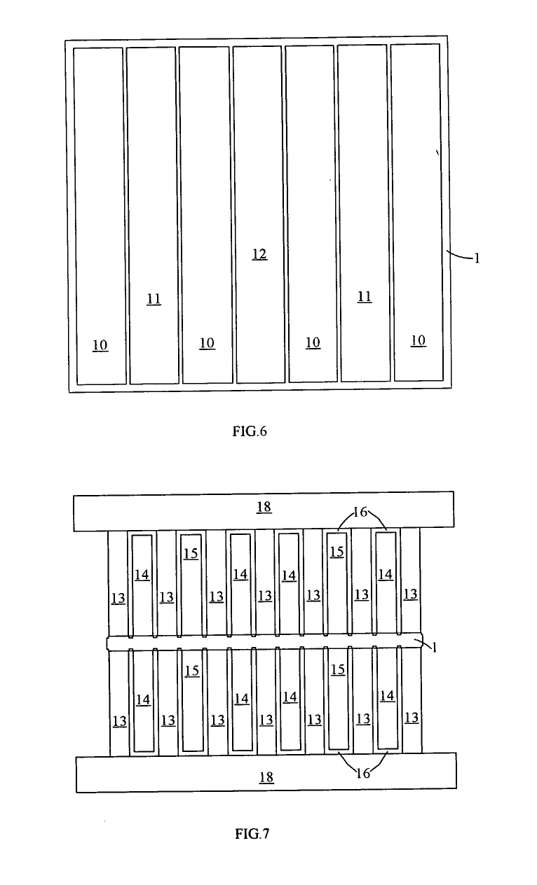

Disposition of splits FIG. 4 comprises lead 5, leg 6, narrow split 7, foot 8, wide split 9.

Non-straightforward splits increase compliance of the leads along all directions.

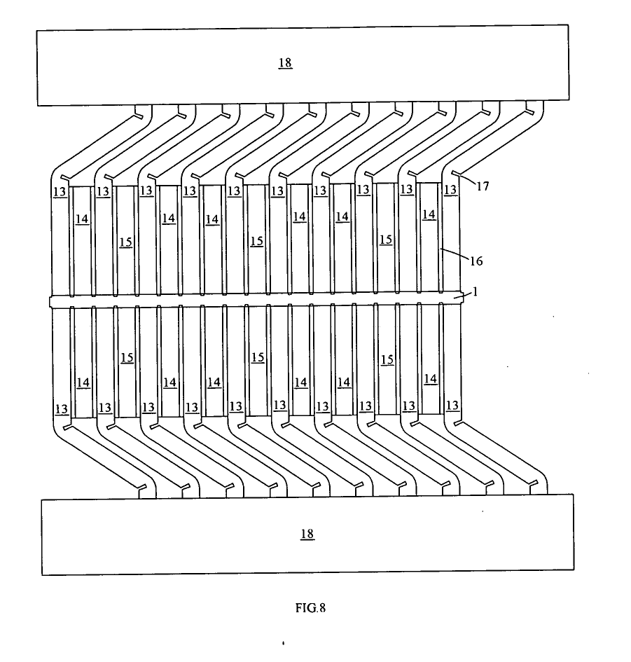

Disposition of splits FIG. 5 comprises lead 5, leg 6, narrow split 7, foot 8, wide split 9.

Planar view of the die with contact pads FIG. 6 comprises chip 1, ordinary channel contact pads 10, gate contact pads 11, thick channel contact pads 12.

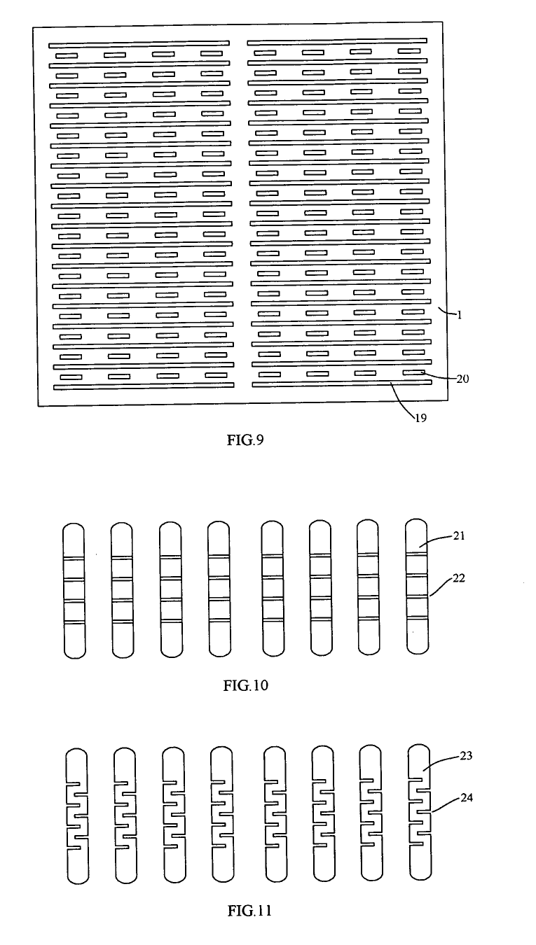

A structure of leads of power transistor FIG. 7 comprises chip 1, inner lead of ordinary channel 13, inner lead of gate 14, inner lead of thick channel 15, isolation 16, external lead of ordinary channel 18 (external leads of gate and thick channel are not shown).

Thickness of the foil is at least a few times greater than thickness of the isolating film.

A structure of leads of power transistor FIG. 8 comprises chip 1, inner lead of ordinary channel 13, inner lead of gate 14, inner lead of thick channel 15, isolation 16, split which are parallel to contact pad 17, external lead of ordinary channel 18 (external leads of gate and thick channel are not shown).

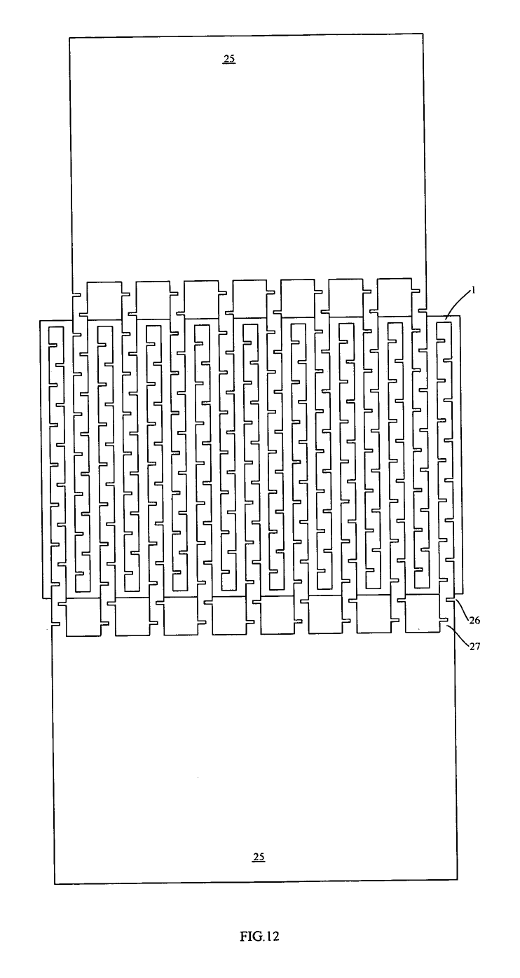

A top view of contact pads of interposer FIG. 9 comprises chip 1, contact pad of great lead 19, contact pad of signal lead 20.

A shape of signal lead FIG. 10 comprises signal lead 21, trench 22.

A shape of signal lead FIG. 11 comprises signal lead 23, split 24.

A disposition two leadframe over chip FIG. 12 comprises chip 1, external lead 25, split 26, inner lead 27.

An inner lead 27 is drawn after soldering. Relative lengthening equals about 10.sup.-3.

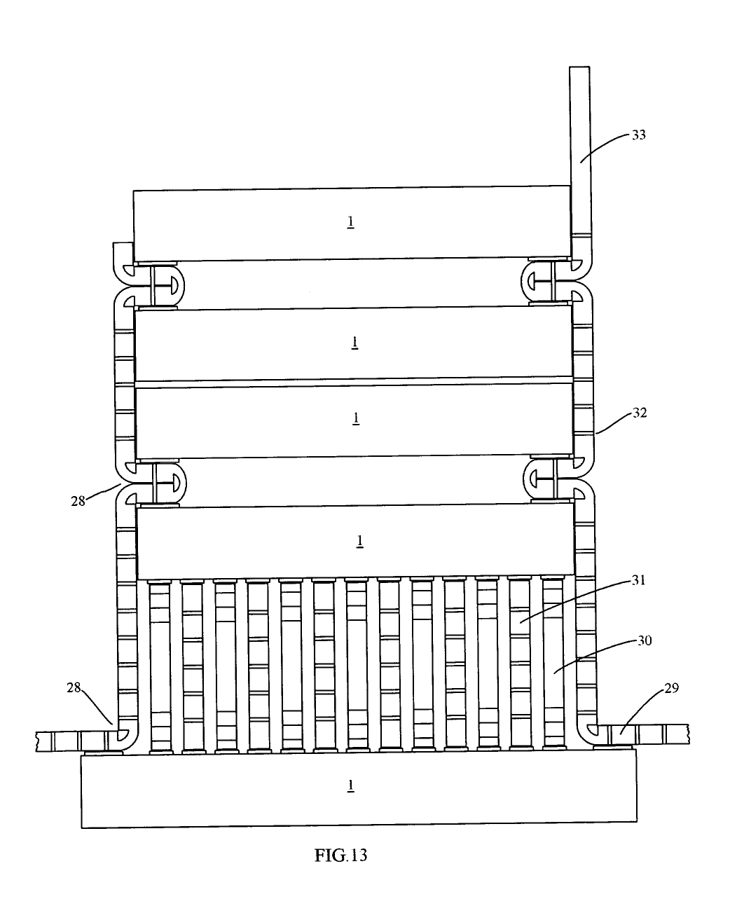

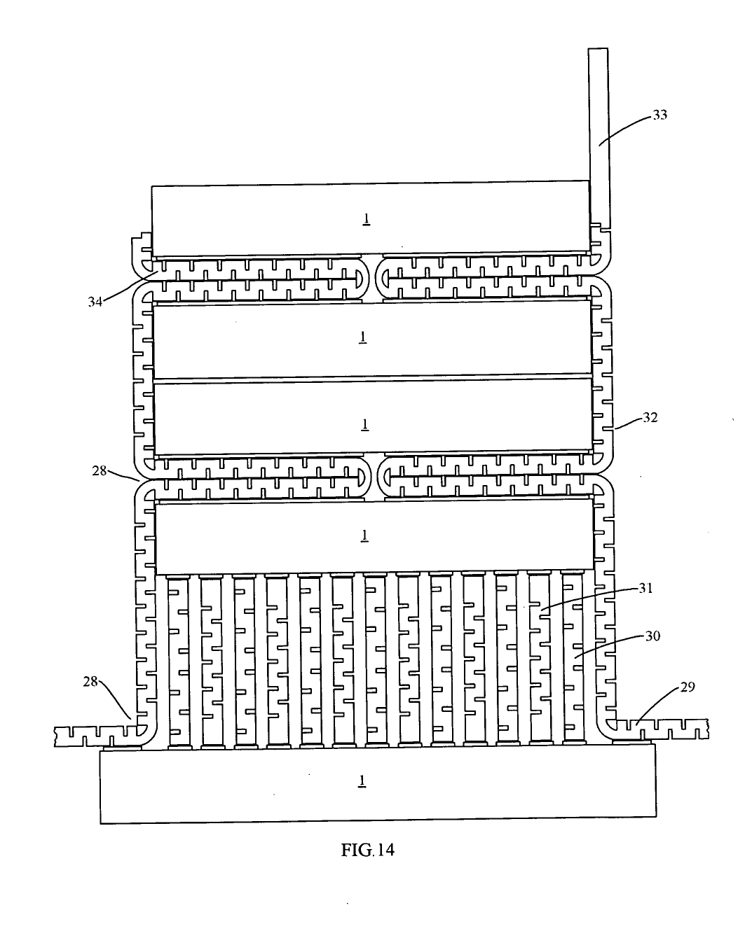

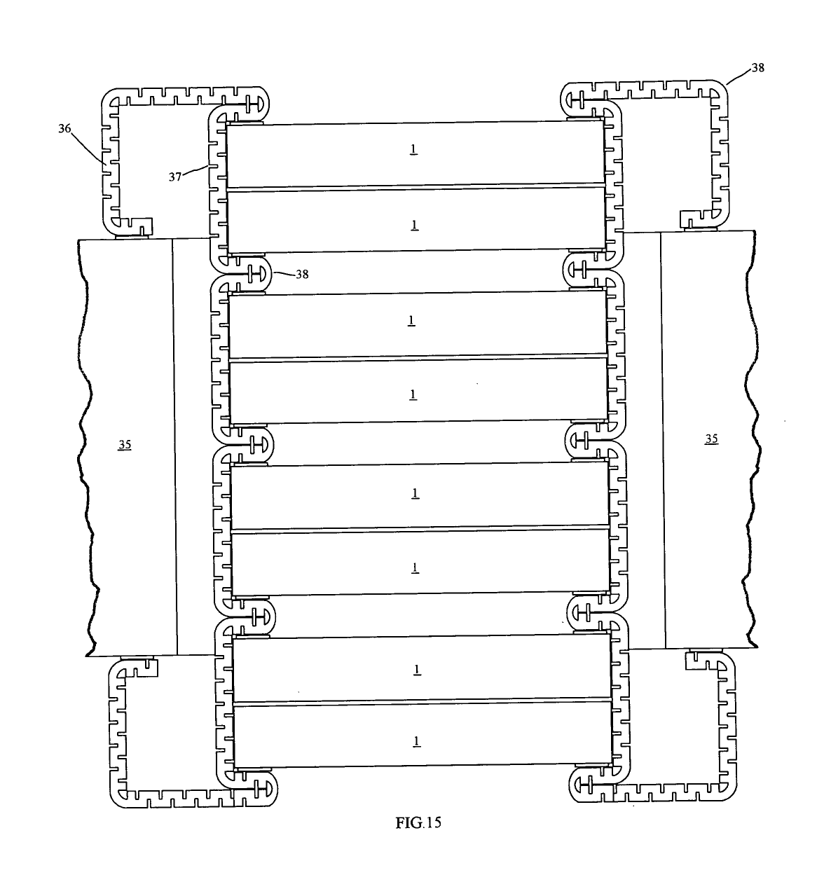

Connection of five electronic component with help offered leads FIG. 13 comprises chips 1, bend 28, inner lead 29, power supply bus 30, signal lead 31, split 32, lead connection strip 33, (isolation are not shown).

Connection of five electronic component with help inner leads FIG. 14 comprises chips 1, bend 28, inner lead 29, power supply bus 30, signal lead 31, trench 32, lead connection strip 33, (isolation are not shown).

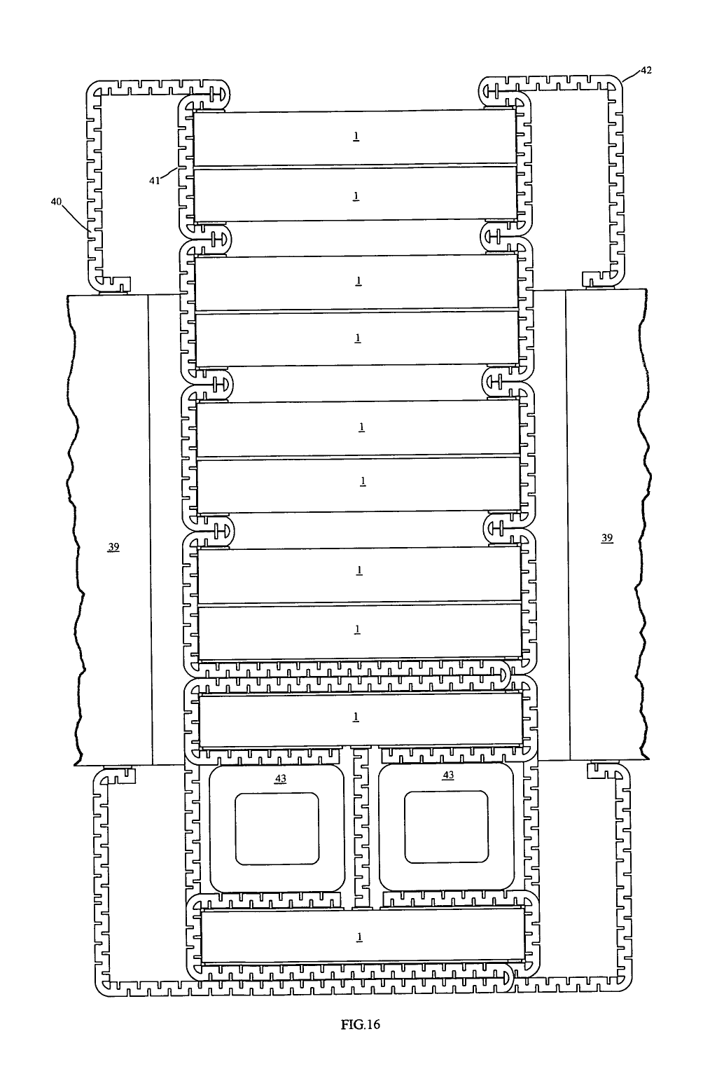

A connection of eight dice with help offered leads FIG. 15 comprises chip 1, board 35, lead 36, trench 37, bend (combination of three bends) 38 (isolation are not shown).

A connection of ten dice with help offered leads FIG. 16 comprises chip 1, board 39, lead 40, trench 41, bend (combination of three bends) 42, power supply bus with water cooler 43 (isolation are not shown).

Heat pass as well as spread through part of leads 40 and water-cooled buses 43. Electrical current flows through leads 40 and water-cooled buses 43. Electrical and thermal resistances of leadframe are small.

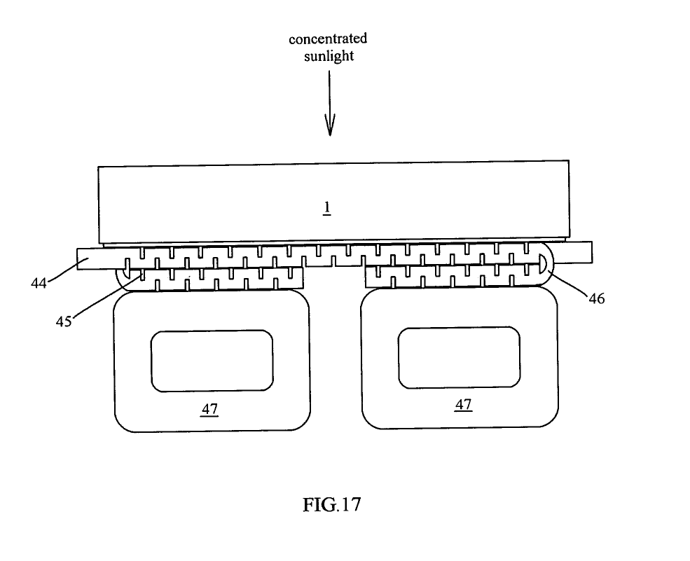

A structure of leads of solar cell FIG. 17 comprises die 1, inner lead 44, trench 45, bend 46, buses with water cooler 47 (isolation are not shown).

Heat pass as well as spread through leads 44 and water-cooled buses 47. Electrical current flows through leads 44 and water-cooled buses 47. Electrical and thermal resistances of leadframe are small.

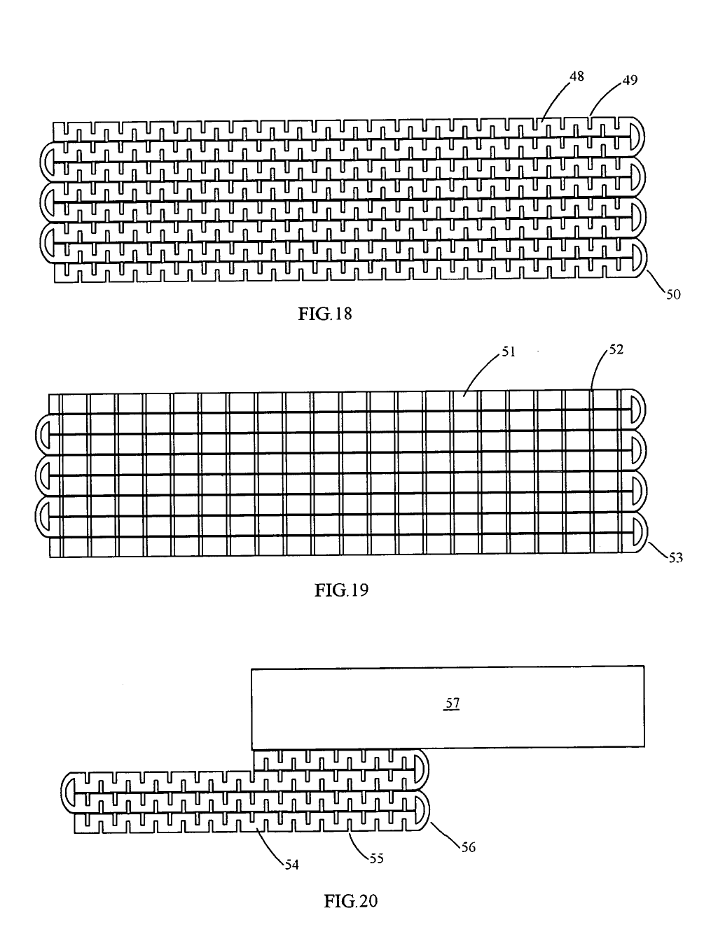

A structure of lead of power device FIG. 18 comprises foil 48, trench 49, bend 50.

A structure of lead of power device FIG. 19 comprises foil 51, split 52, bend 53.

A structure of lead of power device FIG. 20 comprises foil 54, trench 55, bend 56, external lead-heatspreader 57.

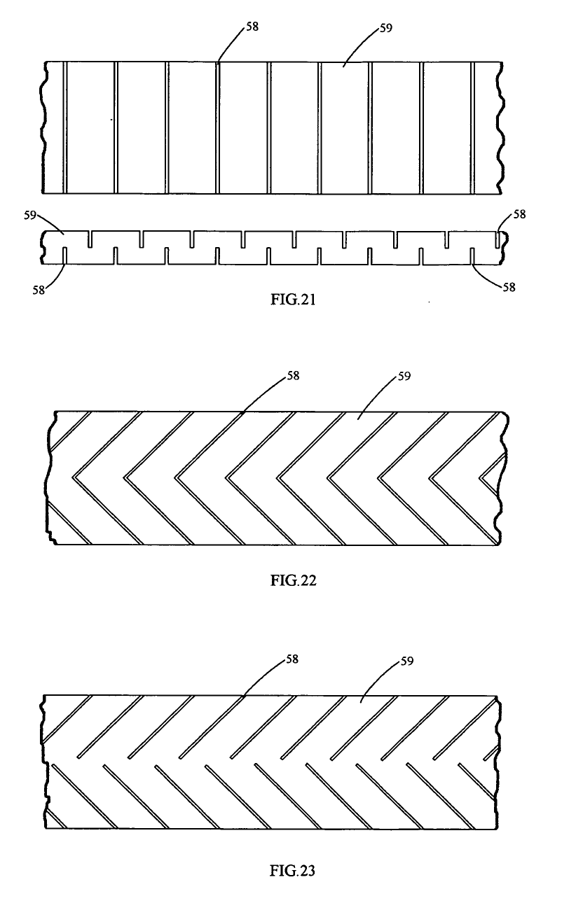

Disposition of trenches of foil FIG. 21 comprises trench 58, foil 59.

Disposition of trenches on one side of foil FIG. 22 comprises trench 58, foil 59. Non-straightforward trenches increase compliance of the leads along all directions.

Disposition of trenches on one side of foil FIG. 23 comprises trench 58, foil 59.

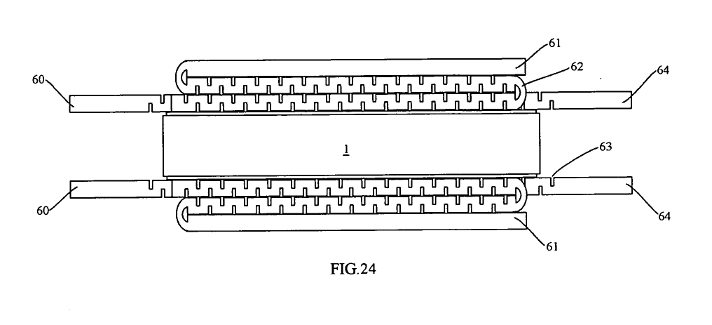

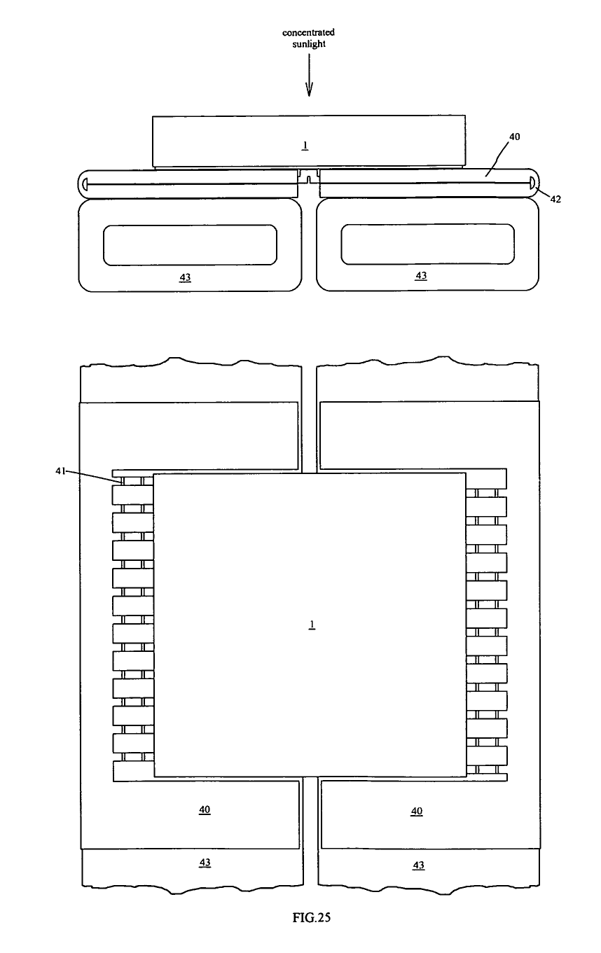

A structure of leads of relatively power transistor FIG. 24 comprises chip 1, lead of gate 60, lead of ordinary channel 61, bend 62, trench 63, lead of thick channel 64.

Thickness of lead (copper foil) equals, for example, 35.times.10.sup.-6 m.

Width of narrow split equals, for example, 2.times.10.sup.-6 m.

Width of wide trench equals, for example, 6.times.10.sup.-5 m.

As a rule, height (width) of inner leads can be greater than the thickness of the foil from 2 to 50 times.

Chip has, for example, a square or rectangular shape.

As a rule, height (width) of inner leads can be greater than the thickness of the foil from 2 to 50 times.

While the invention has been particularly shown and described with reference to the preferred embodiments thereof, it will be understood by those skilled in the art that the foregoing and other changes in form and detail may be made therein without departing from the spirit and the scope of the invention.

1. At least one of leads of a semiconductor device is made of copper foil comprising alternating narrow trenches on both side said foil and/or a row of narrow through splits;
the next of said splits are disposed at a distance several times less than the thickness of said foil;
long narrow facet of said lead is directly connected to at least one of the contact pads of an electronic component;
said splits are disposed near said contact pad.

2. The lead according to claim 1 wherein said splits and said trenches are parallel to each other.

3. The lead according to claim 1 wherein said lead has a height many times greater than said thickness of said foil.

4. The lead according to claim 1 wherein said splits have a length equal to about 20 percent of said height of said lead.

5. The lead according to claim 1 wherein said splits and said trenches are non-straightforward.

6. The lead according to claim 1 wherein said lead is coated with gold or silver.

7. The lead according to claim 1 wherein said lead is connected to said contact pad with solder;
the thickness of said solder is equal to about 3.times.10.sup.-6 m.

8. The lead according to claim 1 wherein said lead is the part of a heatspreader.

9. The leads according to claim 1 further comprising a lead fixing tape.

10. An interposer comprising at least one lead;
said lead is made of copper foil comprising alternating narrow trenches on both side said foil and/or two rows of narrow through splits;
the next of said splits are disposed at a distance several times less than the thickness of said foil;
long narrow facets of said lead is directly connected to contact pads of two electronic components;
said splits are disposed near said contact pads.

11. The interposer according to claim 10 wherein said splits and said trenches are parallel to each other.

12. The interposer according to claim 10 wherein said lead has a height many times greater than said thickness of said foil.

13. The interposer according to claim 10 wherein said splits have a length equal to about 20 percent of said height of said lead.

14. The interposer according to claim 10 wherein said splits and said trenches are non-straightforward.

15. The interposer according to claim 10 wherein said lead is coated with gold or silver.

16. The interposer according to claim 10 wherein said lead is connected to said contact pads with solder;
the thickness of said solder is equal to about 3.times.10.sup.-6 m.

17. The interposer according to claim 10 wherein said lead is the part of a heatspreader.

18. The interposer according to claim 10 further comprising a lead fixing tape.

19. A lead stack comprising a great number of leads of a semiconductor device separated each other by the isolation;
said leads are made of copper foil comprising alternating narrow trenches on both side said foil and/or one or two row of narrow through splits;
long narrow facets of said leads are directly connected to the contact pads one or two electronic components;
said splits are disposed near said contact pads.

20. The lead stack according to claim 19 wherein said lead stack is connected to said contact pads that are a number of parallel strips;
said leads are connected to external leads that are the part of a package.

21. The lead stack according to claim 20 further comprise parallel wide trenches disposed at upper part of inner leads;
said leads are bent along said wide trenches.

22. An interposer comprising great leads and a great number of signal leads;
said great leads are made of copper foil comprising alternating narrow trenches on both side said foil and/or two rows of narrow through splits;
the next of said great lead splits are disposed at a distance several times less than the thickness of said foil;
long narrow facets of said great leads are directly connected to contact pads of two electronic components;
said great lead splits are disposed near said contact pads;
said signal lead is made of copper foil comprising alternating narrow trenches on both side said foil and/or alternating narrow through splits on both sides of said signal lead;
the row said signal leads is disposed between two lead fixing tapes and two said great leads;
said signal leads are directly connected to contact pads of two electronic components.

23. The interposer according to claim 22 wherein said signal lead has a height equal to the height said great leads.

24. The interposer according to claim 22 wherein said splits and said trenches are parallel to each other.

25. The interposer according to claim 22 wherein said signal lead has a width equal to about 2.times.thickness of said foil;
said signal lead splits have a length equal to about 60 percent of said width of said signal lead;
the next of said signal lead splits are disposed at a distance equal to about the width of said signal lead.

26. The interposer according to claim 22 wherein said lead is coated with gold or silver.

27. The interposer according to claim 22 wherein said leads are connected to said contact pads with solder;
the thickness of said solder is equal to about 3.times.10.sup.-6 m.

28. A leadframe comprising a great number of inner leads and at least one external lead;
said leadframe is made of copper foil;
said inner leads comprise alternating narrow trenches on both side said foil and/or alternating narrow through splits on both sides of said leads;
said inner leads can comprise wide trenches;
said inner leads are bent along said wide trenches;
said inner leads are directly connected to contact pads disposed on one or both major surfaces of at least one electronic component;
said inner leads can be formed into a two-layer and/or multilayer structure.

29. The leadframe according to claim 28 wherein said lead has a width equal to about 2.times.thickness of said foil;
said splits have a length equal to about 60 percent of said width of said lead;
the next of said splits are disposed at a distance equal to about the width of said lead.

30. The leadframe according to claim 28 wherein said leads are coated with gold or silver.

31. The leadframe according to claim 28 wherein said inner leads are connected to said contact pads with solder;
the thickness of said solder is equal about 3.times.10.sup.-6 m.

32. The leadframe according to claim 28 further comprising a lead connecting strip.

33-35. (canceled)

36. The leadframe according to claim 28 wherein shape and dimensions layers are different.

37. The lead according to claim 1 wherein the next of said trenches are disposed at a distance equal to approximately the thickness of said foil.

38. The lead according to claim 1 wherein said trench has a depth equal to about 50 percent of said thickness of said foil.

39. The interposer according to claim 10 wherein the next of said trenches are disposed at a distance equal to approximately the thickness of said foil.

40. The interposer according to claim 10 wherein said trench has a depth equal to about 50 percent of said thickness of said foil.

41. The lead stack according to claim 19 wherein the next of said trenches are disposed at a distance equal to approximately the thickness of said foil.

42. The lead stack according to claim 19 wherein said trench has a depth equal to about 50 percent of said thickness of said foil.

43. The interposer according to claim 22 wherein the next of said trenches are disposed at a distance equal to approximately the thickness of said foil.

44. The interposer according to claim 22 wherein said trench has a depth equal to about 50 percent of said thickness of said foil.

45. The leadframe according to claim 28 wherein the next of said trenches are disposed at a distance equal to approximately the thickness of said foil.

46. The leadframe according to claim 28 wherein said trench has a depth equal to about 50 percent of said thickness of said foil.

47. The leadframe according to claim 28 wherein said leadframe is the part of a heatspreader.
